(19) United States
(12) Patent Application Publication
(10) Pub. No.: US 2020/0049768 A1
(43) Pub. Date: Feb. 13, 2020

(54) RELAY WELDING DETECTION DEVICE, POWER SUPPLY CONTROL DEVICE INCLUDING SAME, AND WELDING DETECTION METHOD

(71) Applicant: Panasonic Intellectual Property Management Co., Ltd., Osaka (JP)

(72) Inventors: KOJI MATSUKAWA, Tokyo (JP); TAKASHI NAKAZAWA, Kanagawa (JP); SHIGEO MASAI, Osaka (JP)

(21) Appl. No.: 16/655,591

(22) Filed: Oct. 17, 2019

Related U.S. Application Data
(63) Continuation of application No. PCT/JP2018/016900, filed on Apr. 26, 2018.

(30) Foreign Application Priority Data
May 19, 2017 (JP) 2017-099999

(51) Int. Cl. G01R 31/327; H01H 47/00; G01R 31/00

(52) U.S. Cl. CPC G01R 31/3278; G01R 31/006; H01H 47/002

(57) ABSTRACT

A relay welding detection device includes a voltage generator, first and second resistor strings, and a relay welding detector. A first relay is disposed on a first wiring line connecting a load to a first terminal of a direct-current power supply of a vehicle, and a second relay is disposed on a second wiring line connecting the load to a second terminal of the direct-current power supply. The first resistor string is connected in series to the first terminal of the direct-current power supply and the voltage generator therebetween, and the second resistor string is connected in series to the second terminal of the direct-current power supply and the voltage generator therebetween. The relay welding detector detects a potential at a connection point of two resistors of each of the first and second resistor strings to detect presence or absence of welding in the first relay and the second relay.

### CROSS-REFERENCE TO RELATED APPLICATIONS

This application is a continuation of the PCT International Application No. PCT/JP2018/016900 filed on Apr. 26, 2018, which claims the benefit of foreign priority of Japanese patent application No. 2017-099999 filed on May 19, 2017, the contents all of which are incorporated herein by reference.

### BACKGROUND

### 1. Technical Field

The present disclosure relates to a relay welding detection device capable of detecting whether a relay is welded or not, a power supply control device including the same, and a welding detection method.

### 2. Description of the Related Art

A conventional structure of power supply control device for causing a vehicle to travel, for example, is known. The power supply control device includes a relay disposed between a direct-current power supply and a power supply device. The relay is capable of switching electrical continuity and interruption between them. For example, Japanese Patent Unexamined Publication No. 2011-185812 (hereinafter referred as PTL 1) describes a structure in which respective one of relays is provided for each of a positive electrode wiring line and a negative electrode wiring line. The positive electrode wiring line connects a positive electrode terminal of a direct-current power supply to a power supply device, and the negative electrode wiring line connects a negative electrode terminal of the direct-current power supply to the power supply device.

In addition, the structure disclosed in PTL 1 is provided with two resistors and a welding detection circuit. Each of the two resistors includes a first end connected to either one of the positive electrode wiring or the negative electrode wiring, and a second end connected to a ground. The welding detection circuit includes an alternating current source, a resistor, and a coupling capacitor. This structure detects a voltage between the alternating current source and the resistor, so that the structure can detect presence or absence of welding in the relays provided respectively on the positive electrode wiring and the negative electrode wiring.

### SUMMARY

A relay welding detection device according to the present disclosure is to be applied to a vehicle. The vehicle includes a direct-current power supply, a first relay, a second relay, a first resistor, and a second resistor. The direct-current power supply includes a first terminal and a second terminal that are connected to a load. The first relay is disposed on a first wiring line connecting the first terminal to the load. The second relay is disposed on a second wiring line connecting the second terminal to the load. The first resistor includes a first end connected to a portion of the first wiring line between the first relay and the load, and a second end connected to a ground. The second resistor includes a first end connected to a portion of the second wiring line between the second relay and the load, and a second end connected to the ground. A relay welding detection device according to the present disclosure includes a voltage generator, a first resistor string, a second resistor string, a first switch, a second switch, and a relay welding detector. The voltage generator is connected to the ground, and generates a voltage. The first resistor string includes two resistors connected to each other in series at a first connection point, and is connected in series to the voltage generator and the first terminal of the direct-current power supply between the voltage generator and the first terminal of the direct-current power supply. The second resistor string includes two resistors connected to each other in series at a second connection point, and the second resistor string is connected in series to the voltage generator and the second terminal of the direct-current power supply between the voltage generator and the second terminal of the direct-current power supply. The first switch switches between a connected state and a disconnected state. The first resistor string is connected to the first terminal in the connected state, and is disconnected from the first terminal in the disconnected state. The second switch switches between a connected state and a disconnected state. The second resistor string is connected to the second terminal in the connected state, and is disconnected from the second terminal in the disconnected state. The relay welding detector is connected to the ground, and detects a first potential at the first connection point of the first resistor string and a second potential at the second connection point of the second resistor string. The relay welding detector detects the first potential in a case where the first switch is in the connected state and the second switch is in the disconnected state, and detects presence or absence of welding in the first relay and the second relay based on the first potential, a first determination value using a resistance value of the first resistor, and a second determination value using a resistance value of the second resistor.

A power supply control device according to the present disclosure is to be applied to a vehicle that includes a direct-current power supply including a first terminal and a second terminal that are connected to a load. The power supply control device includes the relay welding detection device as described above, a first relay, a second relay, a first resistor, and a second resistor. The first relay is disposed on a first wiring line connecting the first terminal to the load. The second relay is disposed on a second wiring line connecting the second terminal to the load. The first resistor includes a first end connected to a portion of the first wiring line between the first relay and the load, and a second end connected to a ground. The second resistor includes a first end connected to a portion of the second wiring line between the second relay and the load, and a second end connected to the ground.

A welding detection method according to the present disclosure is a welding detection method to be applied to a vehicle. The vehicle includes a direct-current power supply, a first relay, a second relay, a first resistor, a second resistor, a voltage generator, a first resistor string, a second resistor string, a first switch, and a second switch. The direct-current power supply includes a first terminal and a second terminal that are connected to a load. The first relay is disposed on a first wiring line connecting the first terminal to the load. The second relay is disposed on a second wiring line connecting the second terminal to the load. The first resistor includes a first end connected to a portion of the first wiring line between the first relay and the load, and a second end connected to a ground. The second resistor includes a first end connected to a portion of the second wiring line between the second relay and the load, and a second end connected to the ground. The voltage generator is connected to the ground, and generates a voltage. The first resistor string includes two resistors connected to each other in series at a first connection point, and the first resistor string is connected in series to the voltage generator and the first terminal of the direct-current power supply between the voltage generator and the first terminal of the direct-current power supply. The second resistor string including two resistors connected to each other in series at a second connection point, and the second resistor string is connected in series to the voltage generator and the second terminal of the direct-current power supply between the voltage generator and the second terminal of the direct-current power supply. The first switch switches between a connected state and a disconnected state. The first resistor string is connected to the first terminal in the connected state, and is disconnected from the first terminal in the disconnected state. The second switch switches between a connected state and a disconnected state. The second resistor string is connected to the second terminal in the connected state, and is disconnected from the second terminal in the disconnected state. In this welding detection method, a first potential is detected in a case where the first switch is in the connected state and the second switch is in the disconnected state. Then, presence or absence of welding in the first relay and the second relay is detected based on the first potential, a first determination value using a resistance value of the first resistor, a second determination value using a resistance value of the second resistor.

The present disclosure makes it possible to reliably detect, in an apparatus including a plurality of relays, presence or absence of welding in each of the relays.

### BRIEF DESCRIPTION OF DRAWINGS

FIG. 1 is a diagram illustrating a power supply control device according to an exemplary embodiment of the present disclosure.

FIG. 2 is a view for illustrating welding detection in a case where a first switch is turned on.

FIG. 3 is a view for illustrating welding detection in another case where the first switch is turned on.

FIG. 4 is a view for illustrating welding detection in yet another case where the first switch is turned on.

FIG. 5 is a view for illustrating welding detection in still another case where the first switch is turned on.

FIG. 6 is a view for illustrating welding detection in a case where a second switch is turned on.

FIG. 7 is a view for illustrating welding detection in another case where the second switch is turned on.

FIG. 8 is a view for illustrating welding detection in yet another case where the second switch is turned on.

FIG. 9 is a view for illustrating welding detection in still another case where the second switch is turned on.

FIG. 10 is a flowchart illustrating an operation example when performing welding detection control in the power supply control device.

FIG. 11 is a diagram illustrating a configuration in a case where a relay welding detection device also serves as a leakage detection device in an exemplary embodiment of the present disclosure.

FIG. 12 is a diagram illustrating the configuration in the case where the relay welding detection device also serves as the leakage detection device in the exemplary embodiment of the present disclosure.

### DETAILED DESCRIPTION OF PREFERRED EMBODIMENTS

In the technique disclosed in PTL 1, the voltages detected by the welding detection circuit are equal when only one of the two relays welds. This means that it is impossible to determine which one of the relays has welded.

The present disclosure provides a relay welding detection device, a power supply control device, and a welding detection method that are capable of detecting, in an apparatus including a plurality of relays, presence or absence of welding in each of the relays.

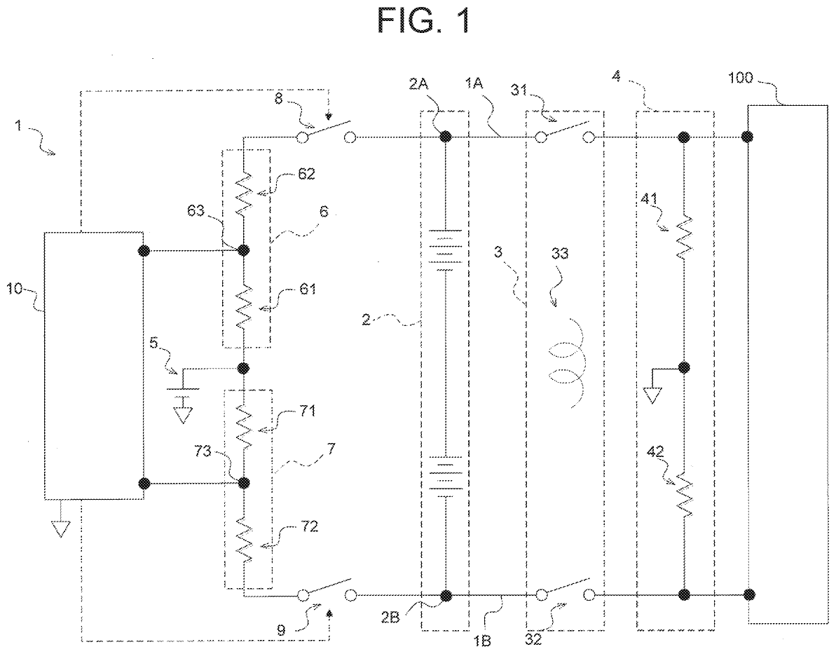

Hereafter, exemplary embodiments of the present disclosure will be described with reference to the drawings. FIG. 1 is a diagram illustrating power supply control device 1 according to the present exemplary embodiment.

Power supply control device 1 is to be mounted to a vehicle including direct-current power supply 2. Power supply control device 1 includes relay unit (or relay assemblage) 3, resistor group 4, voltage generator 5, first resistor string 6, second resistor string 7, first switch 8, second switch 9, and relay welding detector 10.

Direct-current power supply 2 includes positive electrode terminal 2A and negative electrode terminal 2B that are connected to load 100. Load 100 may include, for example, an inverter and a motor for driving the vehicle. Positive electrode terminal 2A corresponds to “first terminal” of the present disclosure, and negative electrode terminal 2B corresponds to “second terminal” of the present disclosure. Load 100, direct-current power supply 2, relay unit 3, and resistor group 4 constitute a vehicle driving device, for example.

Relay unit 3 includes first relay 31 disposed on first wiring line 1A connecting load 100 to positive electrode terminal 2A of direct-current power supply 2, and second relay 32 disposed on second wiring line 1B connecting load 100 to negative electrode terminal 2B of direct-current power supply 2.

Relay unit 3 brings first relay 31 and second relay 32 into an on-state (i.e., a connected state) by passing electric current through electromagnetic coil 33, and brings first relay 31 and second relay 32 into an off-state (i.e., an interrupted or disconnected state) by not passing electric current through electromagnetic coil 33.

Resistor group 4 includes first resistor 41 and second resistor 42. A first end of first resistor 41 is connected to a portion of first wiring line 1A between first relay 31 and load 100, and a second end thereof is connected to a ground. A first end of second resistor 42 is connected to a portion of second wiring line 1B between second relay 32 and load 100 in second wiring line 1B, and a second end thereof connected to the ground. Resistor group 4 is used as, for example, a voltage sensor.

Voltage generator 5 generates a direct-current voltage for causing relay welding detector 10 to detect the presence or absence of welding in first relay 31 and second relay 32. Note that the negative electrode of voltage generator 5 is connected to the ground.

First resistor string 6 includes two resistors, third resistor 61 and fourth resistor 62, which are connected to each other in series. First resistor string 6 is connected in series to voltage generator 5 and positive electrode terminal 2A between voltage generator 5 and positive electrode terminal 2A. First resistor string 6 corresponds to a “resistor string” of the present disclosure.

A first end of third resistor 61 is connected to voltage generator 5, and a second end thereof is connected to fourth resistor 62. A first end of fourth resistor 62 is connected to third resistor 61, and a second end thereof is connected to positive electrode terminal 2A via first switch 8.

A first end of first switch 8 is connected to the second end of fourth resistor 62, and a second end thereof is connected to positive electrode terminal 2A. When first switch 8 is on, first switch 8 brings positive electrode terminal 2A and first resistor string 6 into a connected state. When first switch 8 is off, first switch 8 brings positive electrode terminal 2A and first resistor string 6 into a disconnected state. First switch 8 corresponds to “switch” of the present disclosure.

Second resistor string 7 includes two resistors, fifth resistor 71 and sixth resistor 72, which are connected to each other in series. Second resistor string 7 is connected in series to voltage generator 5 and negative electrode terminal 2B between voltage generator 5 and negative electrode terminal 2B.

A first end of fifth resistor 71 is connected to voltage generator 5, and a second end thereof is connected to sixth resistor 72. A first end of sixth resistor 72 is connected to fifth resistor 71, and a second end thereof is connected to second switch 9.

A first end of second switch 9 is connected to the second end of sixth resistor 72, and a second end thereof is connected to negative electrode terminal 2B. When second switch 9 is on, second switch 9 brings negative electrode terminal 2B and second resistor string 7 into a connected state. When second switch 9 is off, second switch 9 brings negative electrode terminal 2B and second resistor string 7 into a disconnected state.

Relay welding detector 10 detects a potential at first connection point 63 between third resistor 61 and fourth resistor 62, and a potential at second connection point 73 between fifth resistor 71 and sixth resistor 72. First connection point 63 corresponds to a “connection point” of the present disclosure. Note that relay welding detector 10 is connected to a ground that is at the same potential as that of the ground to which resistor group 4 and voltage generator 5 are connected. In other words, relay welding detector 10, resistor group 4, and voltage generator 5 are connected to a common ground.

Relay welding detector 10 detects the presence or absence of welding in first relay 31 and second relay 32 based on a change of the potential at first connection point 63 and a change of the potential at second connection point 73, by turning first switch 8 and second switch 9 on and off.

First, a welding detection method is described, for a case where first switch 8 is on and second switch 9 is off, that is, for a case where a voltage generated by voltage generator 5 causes electric current to pass through a path that is on the side where first switch 8 exists.

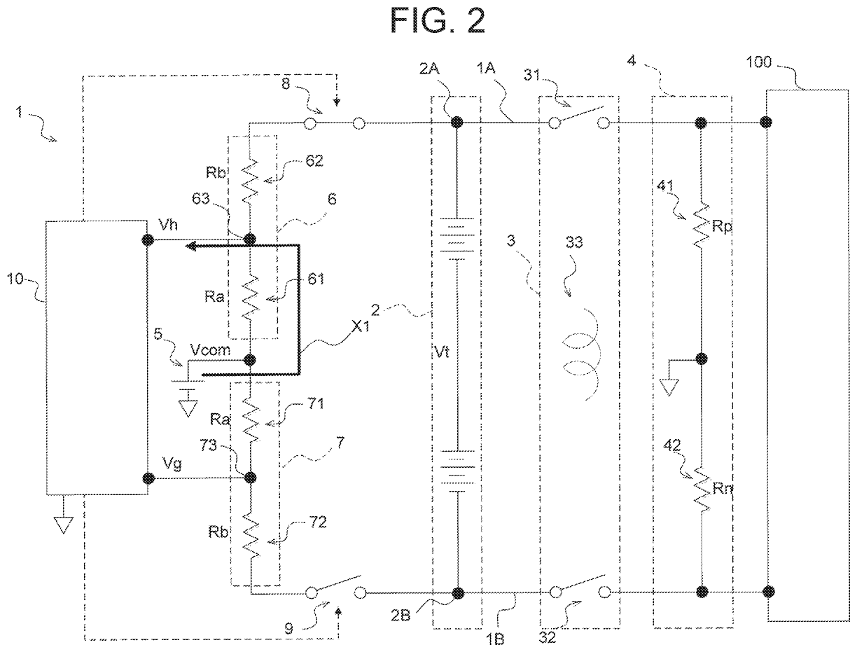

As illustrated in FIG. 2, in the case where both first relay 31 and second relay 32 are in a non-welded state, the paths in first wiring line 1A and second wiring line 1B to resistor group 4 are interrupted (opened). Therefore, the voltage value of voltage generator 5 is directly connected to relay welding detector 10 via third resistor 61 (see arrow X1). Thus, the potential at first connection point 63 detected by relay welding detector 10 is as represented by the following equation (1).

Vh=Vcom (1)

Vh: Potential at first connection point 63 between third resistor 61 and fourth resistor 62

Vcom: Voltage value generated in voltage generator 5

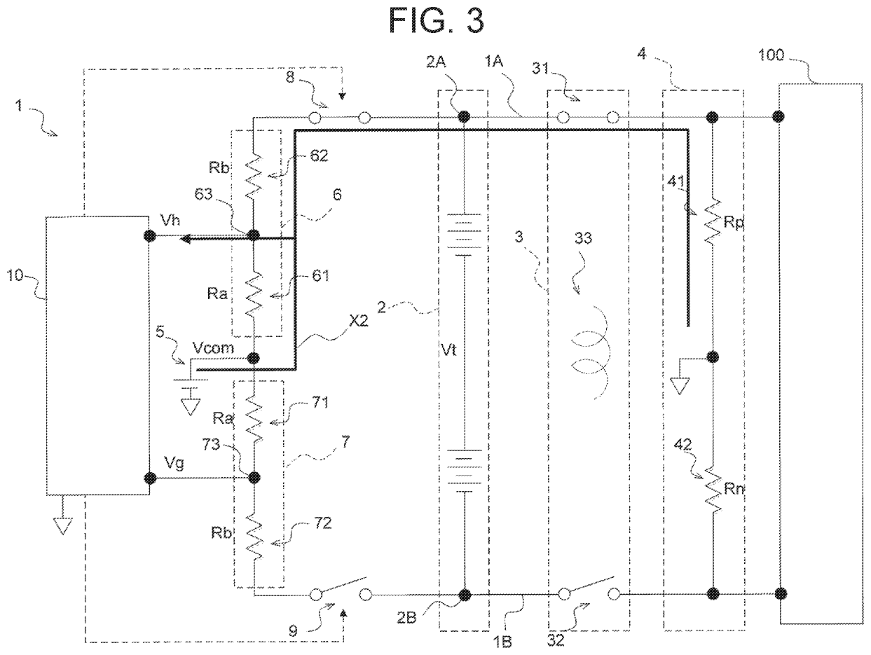

As illustrated in FIG. 3, in the case where first relay 31 is in a welded state and second relay 32 is in a non-welded state, the path to resistor group 4 in first wiring line 1A is connected (closed), while the path to resistor group 4 in second wiring line 1B is interrupted (opened). Therefore, electric current flows in a path (see arrow X2) passing from voltage generator 5 through third resistor 61, fourth resistor 62, first relay 31, and first resistor 41. Accordingly, the potential at first connection point 63 detected by relay welding detector 10 is as represented by the following equation (2).

$$Vh = V com - V com \cdot \{ \frac{Ra}{Ra + Rb + Rp} \} \qquad ( 2 )$$

Ra: Resistance value of third resistor 61

Rb: Resistance value of fourth resistor 62

Rc: Resistance value of first resistor 41

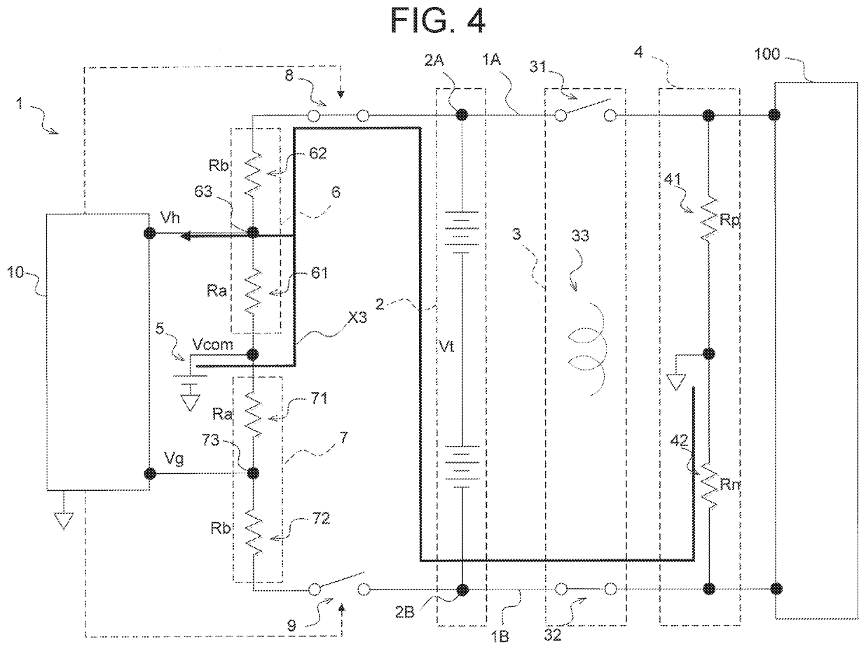

As illustrated in FIG. 4, in the case where first relay 31 is in a non-welded state and second relay 32 is in a welded state, the path to resistor group 4 in first wiring line 1A is interrupted, while the path to resistor group 4 in second wiring line 1B is connected. Therefore, electric current flows in a path (see arrow X3) passing from voltage generator 5 through third resistor 61, fourth resistor 62, direct-current power supply 2, second relay 32, and second resistor 42. Accordingly, the potential at first connection point 63 detected by relay welding detector 10 is as represented by the following equation (3).

$$Vh = V com + Ra \cdot \{ \frac{Vt - V com}{Ra + Rb + Rn} \} \qquad ( 3 )$$

Vt: Voltage value of direct-current power supply 2

Rn: Resistance value of second resistor 42

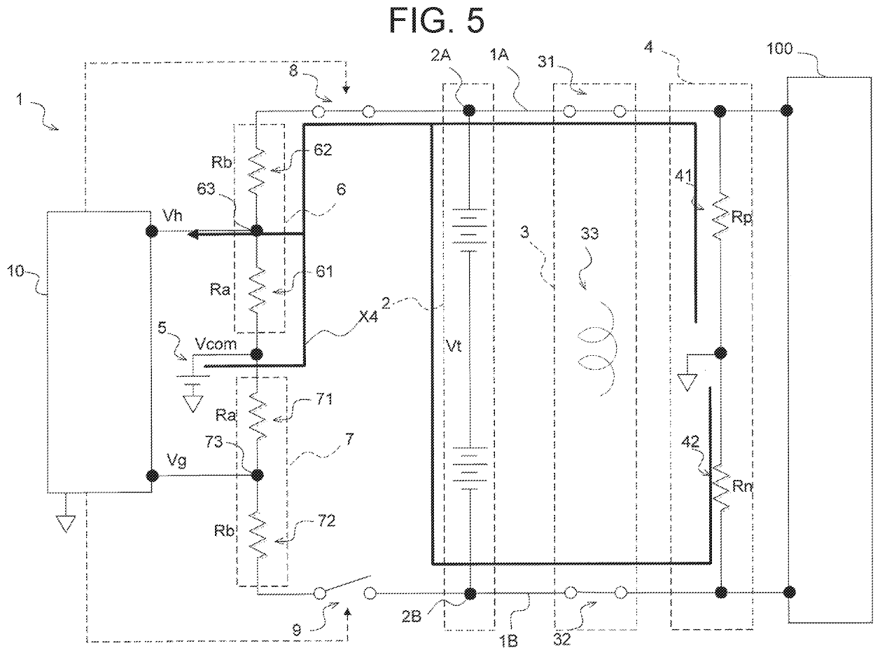

As illustrated in FIG. 5, in the case where first relay 31 is in a welded state and second relay 32 is in a welded state, both of the path to resistor group 4 in first wiring line 1A and the path to resistor group 4 in second wiring line 1B are connected. Therefore, electric current flows in a path (see arrow X4) that connects the path passing from voltage generator 5 through third resistor 61, fourth resistor 62, first relay 31, and first resistor 41 and the path passing from voltage generator 5 through third resistor 61, fourth resistor 62, direct-current power supply 2, second relay 32, and second resistor 42. Accordingly, the potential at first connection point 63 detected by relay welding detector 10 is as represented by the following equation (4).

$$Vh = V com + Ra \cdot \{ \frac{Vt}{Rn + \frac{( Ra + Rb ) \cdot Rp}{( Ra + Rb ) + Rp}} - \frac{V com}{( Ra + Rb ) + \frac{Rn \cdot Rp}{Rn + Rp}} \} \qquad ( 4 )$$

As described above, relay welding detector 10 detects different values of Vh as represented by Equations (1) to (4) by turning on first switch 8 in various cases where first relay 31 and second relay 32 are in different welded states. As a result, in an apparatus including a plurality of relays, it is possible to reliably detect which of the relays has welded or not.

Next, a welding detection method is described, for a case where first switch 8 is off and second switch 9 is on, that is, for a case where a voltage generated by voltage generator 5 causes electric current to pass through a path that is on the side where second switch 9 exists.

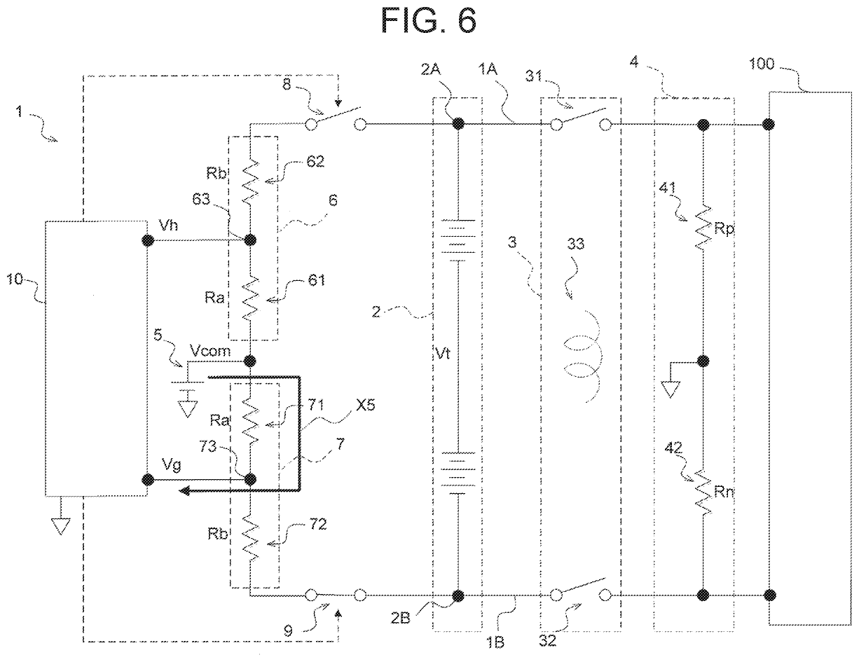

As illustrated in FIG. 6, in the case where both first relay 31 and second relay 32 are in a non-welded state, the paths leading to resistor group 4 in first wiring line 1A and second wiring line 1B are interrupted. Therefore, the voltage value of voltage generator 5 is directly connected to relay welding detector 10 via fifth resistor 71 (see arrow X5). Accordingly, the potential at second connection point 73 detected by relay welding detector 10 is as represented by the following equation (5).

Vg=Vcom (5)

Vg: Potential at second connection point 73 between fifth resistor 71 and sixth resistor 72

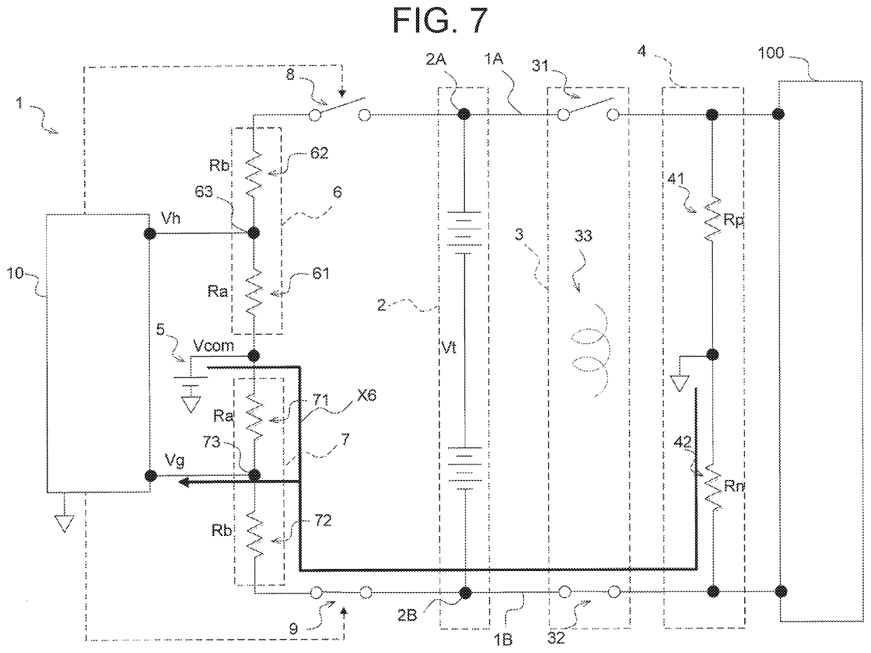

As illustrated in FIG. 7, in the case where first relay 31 is in a non-welded state and second relay 32 is in a welded state, the path to resistor group 4 in first wiring line 1A is interrupted, while the path to resistor group 4 in second wiring line 1B is connected. Therefore, electric current flows in a path (see arrow X6) passing from voltage generator 5 through fifth resistor 71, sixth resistor 72, second relay 32, and second resistor 42. Accordingly, the potential detected by relay welding detector 10 is as represented by the following equation (6).

$$Vg = V com - V com \cdot \{ \frac{Ra}{Ra + Rb + Rn} \} \qquad ( 6 )$$

Ra: Resistance value of fifth resistor 71

Rb: Resistance value of sixth resistor 72

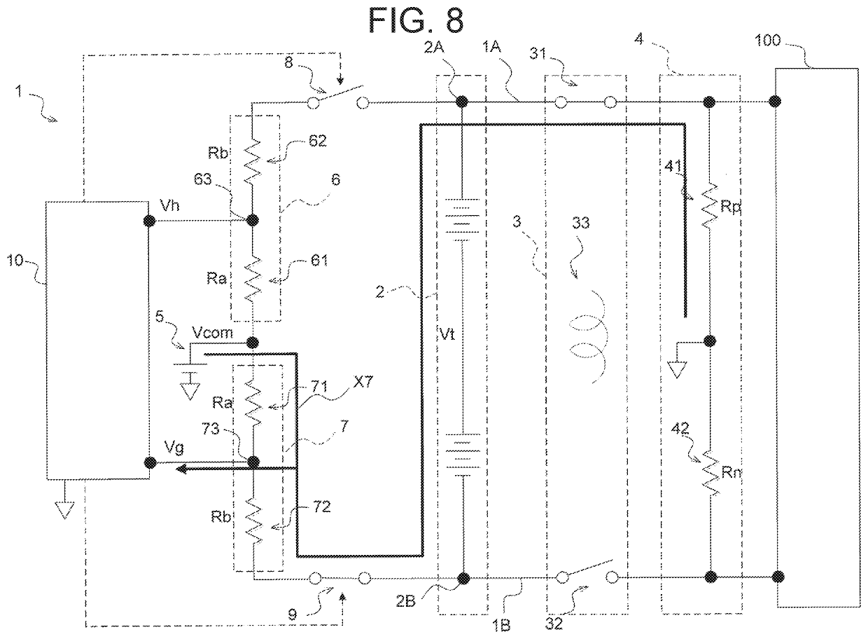

As illustrated in FIG. 8, in the case where first relay 31 is in a welded state and second relay 32 are in a non-welded state, the path to resistor group 4 in first wiring line 1A is connected, while the path to resistor group 4 in second wiring line 1B is interrupted. Therefore, electric current flows in a path (see arrow X7) passing from voltage generator 5 through fifth resistor 71, sixth resistor 72, direct-current power supply 2, first relay 31, and first resistor 41. Accordingly, the potential detected by relay welding detector 10 is as represented by the following equation (7).

$$Vg = V com - Ra \cdot \{ \frac{Vt + V com}{Ra + Rb + Rp} \} \qquad ( 7 )$$

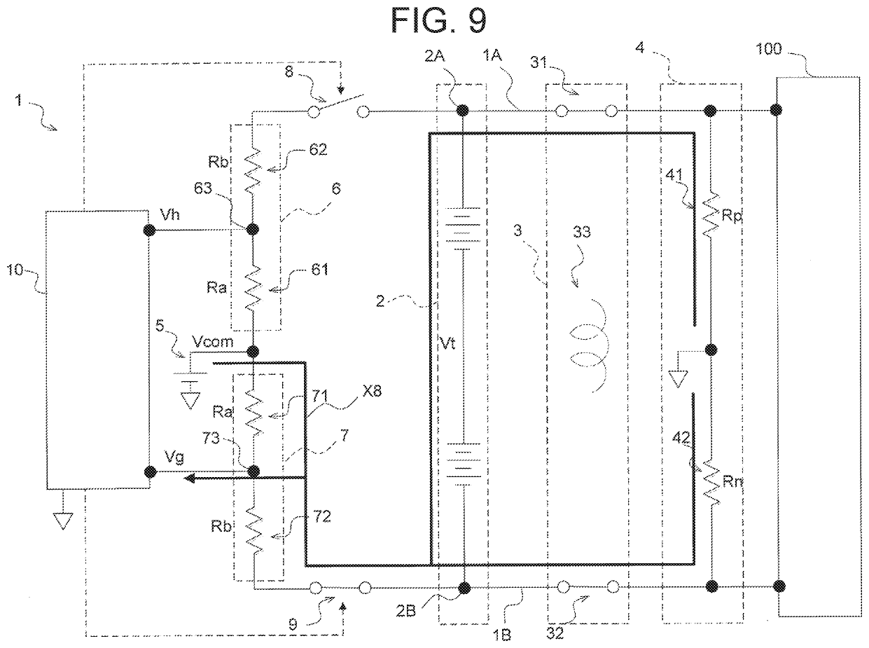

As illustrated in FIG. 9, in the case where first relay 31 is in a welded state and second relay 32 is in a welded state, both of the path to resistor group 4 in first wiring line 1A and the path to resistor group 4 in second wiring line 1B are connected. Therefore, electric current flows in a path (see arrow X8) that connects the path passing from voltage generator 5 through fifth resistor 71, sixth resistor 72, second relay 32, and second resistor 42 and the path passing from voltage generator 5 through fifth resistor 71, sixth resistor 72, direct-current power supply 2, first relay 31, and first resistor 41. Accordingly, the detected potential in relay welding detector 10 is as represented by the following equation (8).

$$Vg = V com - Ra \cdot \{ \frac{Vt}{Rp + \frac{( Ra + Rb ) \cdot Rn}{( Ra + Rb ) + Rn}} + \frac{V com}{( Ra + Rb ) + \frac{Rn \cdot Rp}{Rn + Rp}} \} \qquad ( 8 )$$

As described above, relay welding detector 10 detects different values of Vg as represented by Equations (5) to (8) also by turning on second switch 9, in various cases where first relay 31 and second relay 32 are in different welded states. As a result, in an apparatus including a plurality of relays, it is possible to reliably detect which of the relays has welded or not.

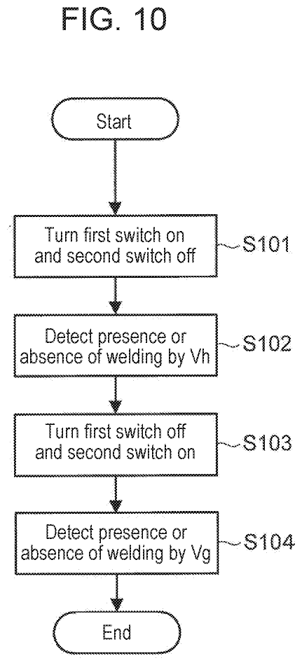

Next, an example of the operation of welding detection control in power supply control device 1 will be described. FIG. 10 is a flowchart illustrating an example of the operation when performing welding detection control in power supply control device 1. The process shown in FIG. 10 is executed when performing welding detection for first relay 31 and second relay 32. When welding detection is performed, first relay 31 and second relay 32 are controlled to be in the off-state.

As illustrated in FIG. 10, relay welding detector 10 turns on first switch 8 and turns off second switch 9 (step S101). Next, relay welding detector 10 detects the presence or absence of welding in first relay 31 and second relay 32 from potential Vh of first connection point 63 between third resistor 61 and fourth resistor 62 (step S102).

When potential Vh is an approximate value of Equation (1), it is detected or determined that “welding is absent” (normality). On the other hand, when potential Vh is an approximate value of any of Equations (2) to (4), it is detected or determined that “welding is present” (abnormality).

More specifically, when potential Vh is an approximate value of Equation (2), it is detected that “welding is present in first relay 31”. When potential Vh is an approximate value of Equation (3), it is detected that “welding is present in second relay 32”. When potential Vh is an approximate value of Equation (4), it is detected that “welding is present both in first relay 31 and second relay 32”.

Next, relay welding detector 10 turns off first switch 8 and turns on second switch 9 (step S103). Next, relay welding detector 10 detects the presence or absence of welding in first relay 31 and second relay 32 from potential Vg of second connection point 73 between fifth resistor 71 and sixth resistor 72 (step S104).

When potential Vg is an approximate value of Equation (5), it is detected that “welding is absent” (normality). On the other hand, if potential Vg is an approximate value of any of Equations (6) to (8), it is detected that “welding is present” (abnormality).

More specifically, when potential Vg is an approximate value of Equation (6), it is detected that “welding is present in second relay 32”. When potential Vg is an approximate value of Equation (7), it is detected that “welding is present in first relay 31”. When potential Vg is an approximate value of Equation (8), it is detected that “welding is present both in first relay 31 and second relay 32”.

Note that it is preferable to output a signal indicating that “welding is present” (abnormality) when it is detected that “welding is present” (abnormality) in either one of step S102 or step S104. In other words, it is preferable to output a signal indicating that “welding is absent” (normality) only when it is detected that “welding is absent” (normality) in both of steps S102 and S104. After step S104, this control process ends.

According to the present exemplary embodiment configured as described above, relay welding detector 10 detects different potential values as represented by Equations (1) to (8) by turning on first switch 8 or second switch 9, in various cases where first relay 31 and second relay 32 are in different welded states. As a result, in an apparatus including a plurality of relays, it is possible to reliably detect which of the relays has welded or not.

Moreover, because the presence or absence of welding in first relay 31 and second relay 32 can be detected in two cases, namely, in the case where first switch 8 is on and second switch 9 is off and in the case where first switch 8 is off and second switch 9 is on, it is possible to carry out more reliable welding detection.

Note that although the foregoing exemplary embodiment has described a structure that includes two switches, first switch 8 and second switch 9, the present disclosure is not limited to this structure. It is also possible to employ a structure that includes either one of first switch 8 and second switch 9.

In the structure in which only second switch 9 is provided in the cases of FIGS. 1 to 9, second switch 9 corresponds to “switch” and “first switch” of the present disclosure, second relay 32 corresponds to “first relay” of the present disclosure, first relay 31 corresponds to “second relay” of the present disclosure, second wiring line 1B corresponds to “first wiring line” of the present disclosure, and first wiring line 1A corresponds to “second wiring line” of the present disclosure, respectively. Also, in the structure in which only second switch 9 is provided, fifth resistor 71 corresponds to “third resistor” of the present disclosure, sixth resistor 72 corresponds to “fourth resistor” of the present disclosure, second connection point 73 corresponds to “connection point” of the present disclosure, second resistor 42 corresponds to “first resistor” of the present disclosure, and first resistor 41 corresponds to “second resistor” of the present disclosure, respectively.

Note that the above-described exemplary embodiment has described that power supply control device 1 includes relay unit 3, resistor group 4, voltage generator 5, first resistor string 6, second resistor string 7, first switch 8, second switch 9, and relay welding detector 10. However, it is also possible that direct-current power supply 2, relay unit 3, resistor group 4, and load 100 may be defined as a vehicle driving device, and voltage generator 5, first resistor string 6, second resistor string 7, first switch 8, second switch 9, and relay welding detector 10 may be defined as a relay welding detection device. That is, it is possible that the combination of power supply control device 1 and direct-current power supply 2 may be divided into a configuration that is necessary for vehicle controlling (i.e., a vehicle driving device) and a configuration that is necessary for abnormality detection (i.e., a relay welding detection device).

Furthermore, a relay welding detection device that includes first resistor string 6, second resistor string 7, first switch 8, second switch 9, and relay welding detector 10 may also serve as a leakage detection device. It is possible to employ a method as disclosed in Japanese Patent Unexamined Publication No. 2007-327856, for example, as a leakage current detection method.

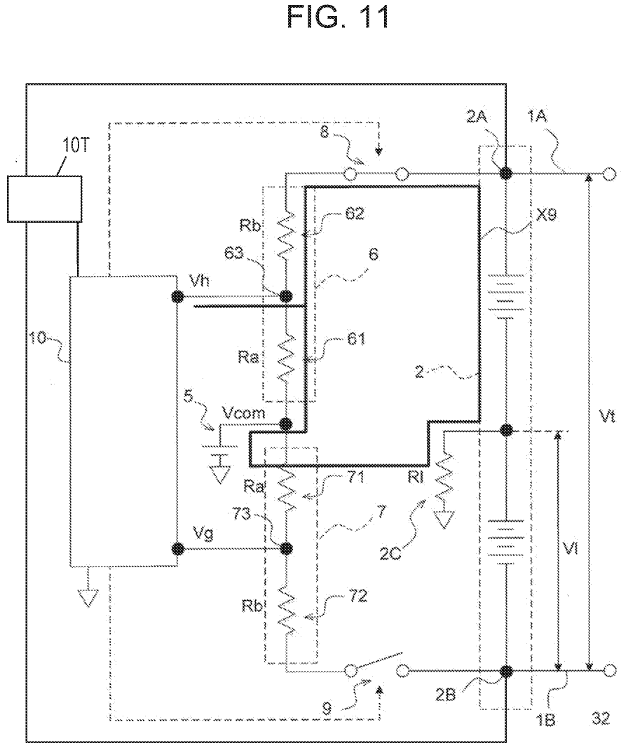

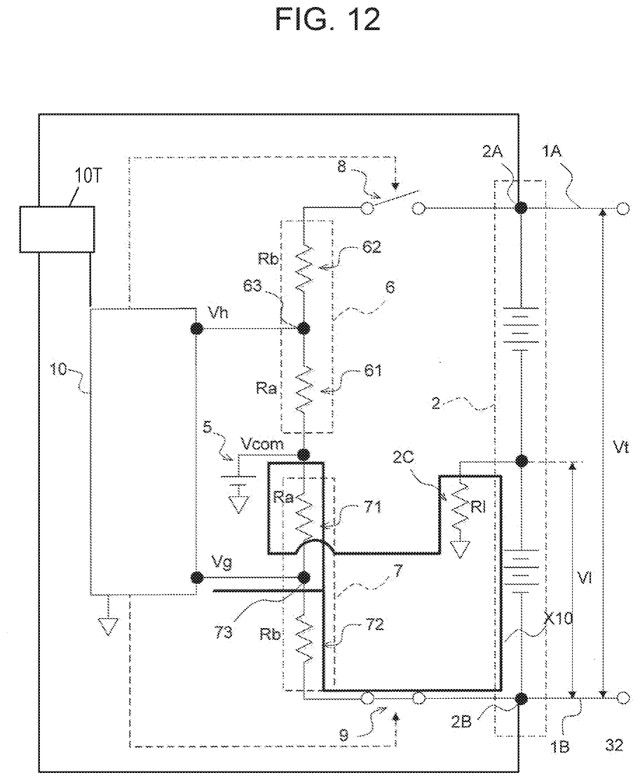

When the relay welding detection device according to the present exemplary embodiment also serves as a leakage detection device, the relay welding detection device includes total voltage detection circuit 10 that detects the total voltage of a higher voltage side (an upper-side power supply) and a lower voltage side (a lower-side power supply) of direct-current power supply 2, as illustrated in FIGS. 11 and 12. As will be described later with reference to FIGS. 11 and 12, relay welding detector 10 calculates resistance value R1 of leakage current resistor 2C that includes a first end connected to the higher voltage side and the lower voltage side of direct-current power supply 2 between the higher voltage side and the lower voltage side and a second end connected to the ground.

Specifically, a leakage current detection method will be described. First, as illustrated in FIG. 11, relay welding detector 10 detects first leakage voltage (Vh) while controlling first switch 8 to be on and second switch 9 to be off. More specifically, turning first switch 8 on and turning second switch 9 off allows electric current to flow in path X9 and relay welding detector 10 detects voltage Vh at that moment.

In addition, as illustrated in FIG. 12, relay welding detector 10 detects second leakage voltage (Vg) while controlling first switch 8 to be off and second switch 9 to be on. Specifically, turning first switch 8 off and turning second switch 9 on allows electric current to flow in path X10, and relay welding detector 10 detects voltage Vg at that moment.

Relay welding detector 10 detects voltage Vh between both ends of third resistor 61 as the first leakage voltage, and voltage Vg between both ends of fifth resistor 71 as the second leakage voltage.

From the first leakage voltage and the second leakage voltage detected in this way, relay welding detector 10 calculates leakage current resistance Rl using the following Equation (9), whereby relay welding detector 10 detects whether current leakage is occurring. When no current leakage is occurring, leakage current resistance Rl of leakage current resistor 2C is infinite. When leakage current resistance Rl is less than a predetermined electrical resistance, relay welding detector 10 determines that current leakage is occurring.

$$Rl = \frac{Ra}{\frac{Vh ( t 1 )}{Vt ( t 1 ) - V com} + \frac{Vg ( t 2 )}{Vt ( t 2 ) + V com}} - ( Ra + Rb ) \qquad ( 9 )$$

Rl: Resistance value of leakage current resistor 2C
Ra: Resistance value of third resistor 61 and fifth resistor 71
Rb: Resistance value of fourth resistor 62 and sixth resistor 72
Vt(t1): Total voltage of direct-current power supply 2 at time t1 at which first switch 8 is controlled to be on and second switch 9 is controlled to be off
Vh(t1): First leakage voltage occurring at third resistor 61 at time t1
Vt(t2): Total voltage of direct-current power supply 2 at time t2 at which first switch 8 is controlled to be off and second switch 9 is controlled to be on
Vg(t2): Leakage voltage occurring at fifth resistor 71 at time t2
Vcom: Voltage value generated in voltage generator 5

Equation (9) can be derived from the following Equations (10) to (13).

$$Vh ( t 1 ) = \frac{Ra}{Rl + Ra + Rb} \cdot \{ ( Vt ( t 1 ) - Vl ( t 1 ) ) - V com \} \qquad ( 10 )$$

Vl(t1): Leakage voltage at time t1

$$Vg ( t 2 ) = \frac{Ra}{Rl + Ra + Rb} \cdot ( Vl ( t 2 ) + V com ) \qquad ( 11 )$$

Vl(t2): Leakage voltage at time t2

Vl(t1)=k·Vt(t1) (12)

k: Constant indicating the position of current leakage location in direct-current power supply 2

Vl(t2)=k·Vt(t2) (13)

Equation (10) represents first leakage voltage Vh(t1) at time t1 under the condition in which first switch 8 is controlled to be on and second switch 9 is controlled to be off by relay welding detector 10, as illustrated in FIG. 11.

Equation (11) represents second leakage voltage Vg(t2) at time t2 under the condition in which first switch 8 is controlled to be off and second switch 9 is controlled to be on, as illustrated in FIG. 12.

Equations (12) and (13) have equality when it is assumed that the position of current leakage does not change. From these Equations (10) to (13), it is possible to derive Equation (9).

Thus, in the present disclosure, the relay welding detection device (first resistor string 6, second resistor string 7, first switch 8, second switch 9, and relay welding detector 10) can also serves as a leakage detection device. This makes it possible to detect relay welding and current leakage while suppressing a cost increase resulting from addition of separate components or the like.

In FIGS. 11 and 12, total voltage detection circuit 10T is provided separately from relay welding detector 10 and connected to relay welding detector 10. However, total voltage detection circuit 10T is not limited to this configuration. For example, relay welding detector 10 may include total voltage detection circuit 10T.

Noted that when only the relay welding detection is performed with the configuration shown in FIG. 1, the relay welding detection device may include voltage generator 5, third resistor 61, and relay welding detector 10 only. In this case, the connection points with fourth resistor 62 are short-circuited. Voltage generator 5 is connected positive electrode terminal 2A and the ground therebetween. The second end of third resistor 61 is connected to positive electrode terminal 2A and the first end thereof is connected to voltage generator 5.

The relay welding detector is connected to the ground, and detects a potential between positive electrode terminal 2A and voltage generator 5 (i.e., the voltage applied to third resistor 61).

In this case, by setting Rb=0, the presence or absence of welding in first relay 31 and second relay 32 can be determined based on the foregoing Equations (1) to (4).

Noted that the relay welding detection device of this configuration may be provided on the negative electrode terminal 2B side, not on the positive electrode terminal 2A side. The relay welding detection device in this case uses fifth resistor 71 as the third resistor in the case where the relay welding detection device is provided on the positive electrode terminal 2A side.

In addition, the foregoing exemplary embodiments merely illustrated examples of embodiments of the present disclosure, and they are not intended to limit the scope of the present disclosure. Accordingly, the present disclosure may be embodied in various ways without departing from the subject matter or the principles of the present disclosure. For example, relay unit 3 may be constructed of an integrated relay so that first relay 31 and second relay 32 can be turned on and off simultaneously.

A power supply control device of the present disclosure is useful for a relay welding detection device that is capable of reliably detecting, in an apparatus including a plurality of relays, the presence or absence of welding in any of the relays, a power supply control device using the same, and a welding detection method.

What is claimed is:

1. A relay welding detection device to be applied to a vehicle, the vehicle including:
a direct-current power supply including a first terminal and a second terminal both connected to a load;
a first relay disposed on a first wiring line connecting the first terminal to the load;
a second relay disposed on a second wiring line connecting the second terminal to the load;
a first resistor including a first end connected to a portion of the first wiring line between the first relay and the load, and a second end connected to a ground; and
a second resistor including a first end connected to a portion of the second wiring line between the second relay and the load, and a second end connected to the ground;
the relay welding detection device comprising:
a voltage generator configured to generate a voltage, the voltage generator connected to the ground;
a first resistor string including two resistors connected to each other in series at a first connection point, the first resistor string being connected in series to the voltage generator and the first terminal of the direct-current power supply between the voltage generator and the first terminal of the direct-current power supply;
a second resistor string including two resistors connected to each other in series at a second connection point, the second resistor string being connected in series to the voltage generator and the second terminal of the direct-current power supply between the voltage generator and the second terminal of the direct-current power supply;
a first switch configured to switch between a first connected state and a first disconnected state, the first resistor string being connected to the first terminal in the first connected state, and the first resistor string being disconnected from the first terminal in the first disconnected state;
a second switch configured to switch between a second connected state and a second disconnected state, the second resistor string being connected to the second terminal in the second connected state, and the second resistor string being disconnected from the second terminal in the second disconnected state; and
a relay welding detector connected to the ground, and configured to detect a first potential at the first connection point of the first resistor string and a second potential at the second connection point of the second resistor string,
wherein the relay welding detector is configured to detect the first potential at the first connection point of the first resistor string in a case where the first switch is in the first connected state and the second switch is in the second disconnected state, and detect presence or absence of welding in the first relay and the second relay based on the first potential, a first determination value using a resistance value of the first resistor, and a second determination value using a resistance value of the second resistor.

2. The relay welding detection device according to claim 1,
wherein the relay welding detector is further configured to detect the second potential in a case where the first switch is in the first disconnected state and the second switch is in the second connected state, and detect presence or absence of welding in the first relay and the second relay based on the second potential, a third determination value using the resistance value of the first resistor, and a fourth determination value using the resistance value of the second resistor.

3. The relay welding detection device according to claim 1,
wherein the first resistor string includes a third resistor and a fourth resistor;
an end of the third resistor that is opposite the first connection point is connected to the voltage generator; and
an end of the fourth resistor that is opposite the first connection point is connected to the first terminal.

4. The relay welding detection device according to claim 3,
wherein the relay welding detector is configured to determine that the first relay is in a welded state and the second relay is in a non-welded state upon finding that a potential Vh at the first connection point satisfies Equation 1:
$$Vh = Vcom - Vcom \cdot \{ \frac{Ra}{Ra + Rb + Rp} \} , \qquad ( Eq . 1 )$$
where Vcom is a voltage value generated in the voltage generator, Rp is a resistance value of the first resistor, Ra is a resistance value of the third resistor, and Rb is a resistance value of the fourth resistor.

5. The relay welding detection device according to claim 3,
wherein the relay welding detector is configured to determine that the first relay is in a non-welded state and the second relay is in a welded state upon finding that a potential Vh at the first connection point satisfies Equation 2:
$$Vh = Vcom + Ra \cdot \{ \frac{Vt - V com}{Ra + Rb + Rn} \} , \qquad ( Eq . 2 )$$
where Vt is a voltage value of the direct-current power supply, Vcom is a voltage value generated in the voltage generator, Rn is a resistance value of the second resistor, Ra is a resistance value of the third resistor, and Rb is a resistance value of the fourth resistor.

6. The relay welding detection device according to claim 3,
wherein the relay welding detector is configured to determine that both the first relay and the second relay are in a non-welded state upon finding that a potential at the first connection point is a voltage value generated in the voltage generator.

7. The relay welding detection device according to claim 3,
wherein the relay welding detector is configured to determine that both the first relay and the second relay are in a welded state upon finding that a potential Vh at the first connection point satisfies Equation 3:
$$Vh = V com + Ra \cdot \{ \frac{Vt}{Rn + \frac{( Ra + Rb ) \cdot Rp}{( Ra + Rb ) + Rp}} - \frac{V com}{( Ra + Rb ) + \frac{Rn \cdot Rp}{Rn + Rp}} \} , \qquad ( Eq . 3 )$$
where Vt is a voltage value of the direct-current power supply, Vcom is a voltage value generated in the voltage generator, Rp is a resistance value of the first resistor, Rn is a resistance value of the second resistor, Ra is a resistance value of the third resistor, and Rb is a resistance value of the fourth resistor.

8. The relay welding detection device according to claim 1, further comprising a total voltage detection circuit configured to detect a total voltage between a higher voltage side and a lower voltage side of the direct-current power supply,
wherein the relay welding detector is configured to detect presence or absence of current leakage based on the total voltage, the first potential in a case where the first switch is in the first connected state and the second switch is in the second disconnected state, and the second potential in a case where the first switch is in the first disconnected state and the second switch is in the second connected state.

9. A welding detection method to be applied to a vehicle including:
a direct-current power supply including a first terminal and a second terminal both connected to a load;
a first relay disposed on a first wiring line connecting the first terminal to the load;
a second relay disposed on a second wiring line connecting the second terminal to the load;
a first resistor including a first end connected to a portion of the first wiring line between the first relay and the load, and a second end connected to a ground;
a second resistor including a first end connected to a portion of the second wiring line between the second relay and the load, and a second end connected to the ground;
a voltage generator configured to generate a voltage, the voltage generator connected to the ground;
a first resistor string including two resistors connected to each other in series at a first connection point, the first resistor string being connected in series to the voltage generator and the first terminal of the direct-current power supply between the voltage generator and the first terminal of the direct-current power supply;
a second resistor string including two resistors connected to each other in series at a second connection point, the second resistor string being connected in series to the voltage generator and the second terminal of the direct-current power supply between the voltage generator and the second terminal of the direct-current power supply;
a first switch configured to switch between a first connected state and a first disconnected state, the first resistor string being connected to the first terminal in the first connected state, and the first resistor string being disconnected from the first terminal in the first disconnected state; and
a second switch configured to switch between a second connected state and a second disconnected state, the second resistor string being connected to the second terminal in the second connected state, and the second resistor string being disconnected from the second terminal in the second disconnected state;
the welding detection method comprising:
detecting the first potential in a case where the first switch is in the first connected state and the second switch is in the second disconnected state; and
detecting presence or absence of welding in the first relay and the second relay based on the first potential, a first determination value using a resistance value of the first resistor, a second determination value using a resistance value of the second resistor.

10. A power supply control device to be applied to a vehicle including a direct-current power supply having a first terminal and a second terminal both connected to a load, the power supply control device comprising:
a first relay disposed on a first wiring line connecting the first terminal to the load;
a second relay disposed on a second wiring line connecting the second terminal to the load;
a first resistor including a first end connected to a portion of the first wiring line between the first relay and the load, and a second end connected to a ground;
a second resistor including a first end connected to a portion of the second wiring line between the second relay and the load in the second wiring line, and a second end connected to the ground; and
the relay welding detection device according to claim 1.
